(19) United States
(12) Patent Application Publication
(10) Pub. No.: US 2026/0353572 A1
(43) Pub. Date: Nov. 5, 2026

(54) METHOD FOR APPLYING COMPONENT-EMBEDDED PACKAGING UNIT TO PCB

(71) Applicant: WUS PRINTED CIRCUIT KEPZ (KUNSHAN) CO., LTD., Suzhou (CN)

(72) Inventors: Min LIU, Suzhou (CN); Dechi KONG, Suzhou (CN); CHENG PO YU, Suzhou (CN)

(73) Assignee: WUS PRINTED CIRCUIT KEPZ (KUNSHAN) CO., LTD., Suzhou (CN)

(21) Appl. No.: 19/654,403

(22) Filed: Apr. 21, 2026

Related U.S. Application Data
(63) Continuation of application No. PCT/CN2025/134241, filed on Nov. 12, 2025.

(30) Foreign Application Priority Data
Nov. 14, 2024 (CN) 202411625726.4

(51) Int. Cl. H05K 3/46; H05K 1/182; H05K 3/00; H05K 3/42

(52) U.S. Cl. CPC H05K 3/4697; H05K 3/0029; H05K 3/0047; H05K 3/0067; H05K 3/423; H05K 1/182; H05K 2203/061; H05K 2203/0723; H05K 2203/107

(57) ABSTRACT

This application discloses a method for applying a component-embedded packaging unit to a PCB. The method includes: processing a second PCB substrate based on design requirements to form a cavity, where a second copper layer is provided on a surface of the cavity-formed second PCB substrate; embedding the component-embedded packaging unit into the cavity vertically; and laying prepreg and copper foil on a surface of the second copper layer sequentially, performing lamination, forming an externally connected laser via at a lead of a component, and electroplating the laser via with copper to enable electrical connection in the PCB. In this application, the component-embedded packaging unit is integrated and packaged as a small unit and then embedded into other different PCBs, thereby providing flexibility of application. In addition, compared with the conventional horizontal structure, the vertical embedding reduces planar footprint and increases current-carrying density.

### RELATED APPLICATIONS

The present patent document is a continuation of PCT/CN2025/134241, filed Nov. 12, 2025, which claims the benefit of priority to Chinese Patent Application No. 202411625726.4, filed Nov. 14, 2024, and entitled “METHOD FOR APPLYING COMPONENT-EMBEDDED PACKAGING UNIT TO PCB” the entire contents of each of which are incorporated herein by reference.

### TECHNICAL FIELD

This application relates to the technical field of printed circuit boards, and in particular, to a method for applying a component-embedded packaging unit to a printed circuit board (PCB).

### BACKGROUND

With the rapid development of the technology industry over the past decades, electronic devices keep evolving and advancing technologically. The functions of an electronic device have become increasingly complex and diversified, resulting in increasingly stringent requirements for component packaging and the application of PCBs. Due to the diversification of application requirements of electronic devices, conventional packaging methods and PCB manufacturing methods can no longer meet the rapidly changing needs of society. Further research is therefore required to enhance the current-carrying capacity, reduce losses, and improve the power handling capability and efficacy.

### SUMMARY

An objective of this application is to provide a method for applying a component-embedded packaging unit to a PCB to overcome the disadvantages of the prior art. By embedding and packaging a component to form a unit, a lead that is externally exposed at the sidewall is formed, and then the component-embedded packaging unit is vertically embedded into a second PCB substrate, and a metallized via that provides electrical interconnection between upper and lower layers is created at the lead to enable electrical conduction.

To achieve the above objective, this application puts forward the following technical solutions:

According to a first aspect, this application provides a method for applying a component-embedded packaging unit to a PCB. The method includes:
processing a second PCB substrate based on design requirements to form a cavity, where a second copper layer is provided on a surface of the cavity-formed second PCB substrate;
embedding the component-embedded packaging unit into the cavity vertically; and
laying prepreg and copper foil on a surface of the second copper layer sequentially, performing lamination, forming an externally connected laser via at a lead of a component, and electroplating the laser via with copper to enable electrical connection in the PCB.

Further, a manufacturing process of the component-embedded packaging unit includes:
drilling a via in the first PCB substrate based on design requirements and performing copper electroplating so that a first copper layer is provided on a surface of the first PCB substrate, and performing pattern design on the first copper layer to generate a placement region;
forming a first recess in a preset placement region of the first PCB substrate, and extending a bottom of the first recess to the first copper layer at a bottom of the first PCB substrate;
attaching the component to the first copper layer at the bottom of the first recess;
laying prepreg and copper foil on a component-attached side of the first PCB substrate sequentially, and performing lamination;
forming a second recess in the prepreg and the copper foil to enable external conduction of the component;
performing copper electroplating on the second recess at a top of the component to generate a metallized filler layer;
performing copper electroplating on a top surface and a bottom surface of the laminated first PCB substrate to thicken the surfaces and form a thickening copper layer on each of the surfaces; and
performing pattern design on the thickening copper layer to form a top lead and a bottom lead of the component and obtain a finished component-embedded packaging unit.

Further, during the electroplating on the top surface and the bottom surface of the laminated first PCB substrate to thicken the surfaces, the surfaces are thickened by at least more than 2 oz.

Further, the component is attached to the first copper layer through a soldering layer formed by silver-sintering or eutectic soldering.

Further, the bottom lead of the component extends to and is exposed at a sidewall through the soldering layer and an etched pattern. The top lead of the component extends to and is exposed at the sidewall through a metal-filled second recess and an etched pattern.

Further, dimensions of the cavity of the second PCB substrate are larger than dimensions of the component-embedded packaging unit, with a single-side clearance ranging from 100 μm to 300 μm. A thickness of the second PCB substrate matches a thickness of the component, with a deviation within +/−100 μm.

Further, the first PCB substrate/second PCB substrate is a single-layer core board or a whole formed by laminating a plurality of core boards.

Further, a thickness of the first copper layer at a bottom of the first PCB substrate is not less than 1 oz, and a board thickness is greater than a thickness of the component.

Further, dimensions of the first recess are larger than dimensions of the component, with a single-side clearance ranging from 100 μm to 200 μm.

Further, one or more components are embedded in the component-embedded packaging unit.

Compared with the prior art, this application achieves at least the following beneficial effects:

This application provides a method for applying a component-embedded packaging unit to a PCB. Based on PCB fabrication processes, this application implements a highly integrated component-embedded package, and forms a lead that can be exposed at the sidewall. The component-embedded packaging unit is vertically embedded into the second PCB substrate, and a metallized via that provides electrical interconnection between upper and lower layers is created at the lead to form a circuit distribution oriented perpendicular to the component. Compared with a conventional planar power supply structure, for the same current-carrying capacity, this application reduces the planar footprint, and increases the current-carrying density per unit area by several times or more. Further, the copper surface structure in the vertical direction improves the heat dissipation distribution of the system, reduces losses, and improves energy efficiency, thereby being of high applicability and far-reaching significance.

### BRIEF DESCRIPTION OF DRAWINGS

FIG. 1 is a schematic diagram of vertically embedding a component-embedded packaging unit in a second PCB substrate according to an embodiment of this application;

FIG. 2 is a schematic diagram of a conventional planar power supply structure according to an embodiment of this application;

FIG. 3 is a schematic diagram of a vertically embedded structure in a PCB according to an embodiment of this application;

FIG. 4 is a schematic diagram of drilling, electroplating, and patterning a first PCB substrate based on design requirements according to an embodiment of this application;

FIG. 5 is a schematic diagram of forming a first recess according to an embodiment of this application;

FIG. 6 is a schematic diagram of attaching a component to a first copper layer by silver-sintering or eutectic soldering or other means according to an embodiment of this application;

FIG. 7 is a schematic diagram of laminating prepreg and copper foil stacked on a first PCB substrate according to an embodiment of this application;

FIG. 8 is a schematic diagram of forming a second recess according to an embodiment of this application;

FIG. 9 is a schematic diagram of electroplating a second recess and electroplating and thickening an outer copper layer according to an embodiment of this application; and

FIG. 10 is a schematic diagram of a component-embedded packaging unit according to an embodiment of this application.

List of reference signs: 1. first PCB substrate; 2. first recess; 3. component; 4. soldering layer; 5. copper foil; 6. prepreg; 7. second recess; 8. metallized filler layer; 9. component-embedded packaging unit; 10.1. top lead of component; 10.2. bottom lead of component; 11. metallized vias above and below the lead; 12. second PCB substrate.

### DETAILED DESCRIPTION

The following describes this application in further detail with reference to accompanying drawings. The following embodiments are merely intended to describe the technical solutions of this application more clearly, but not intended to limit the protection scope of this application.

Understandably, in the description of this application, a directional or positional relationship indicated by the terms such as “center”, “longitudinal”, “transverse”, “up”, “down”, “front”, “rear”, “left”, “right”, “vertical”, “horizontal”, “top”, “bottom”, “in”, and “out” is a directional or positional relationship based on the illustration in the accompanying drawings, and is merely intended for ease or brevity of description of this application, but does not mean or imply that the indicated device or component is necessarily located in the specified direction or constructed or operated in the specified direction. Therefore, such terms are not to be understood as a limitation on this application. In addition, the terms such as “first” and “second” are used merely for ease of description, but not to indicate or imply relative importance or implicitly specify the number of technical features mentioned. Therefore, a feature qualified by “first”, “second” and the like may explicitly or implicitly include one such feature or a plurality of the features. In the description of this application, unless otherwise specified, “a plurality of” means two or more.

In the description of this application, it is hereby noted that, unless otherwise expressly specified and qualified, the terms “mount”, “concatenate”, and “connect” are generic in a broad sense, for example, mean a fixed connection, a detachable connection, or an integrated connection; mean a mechanical connection or electrical connection; mean a direct connection or indirect connection implemented through an intermediary; or mean internal communication between two components. A person of ordinary skill in the art can understand the specific meanings of the terms in this application according to the specific context.

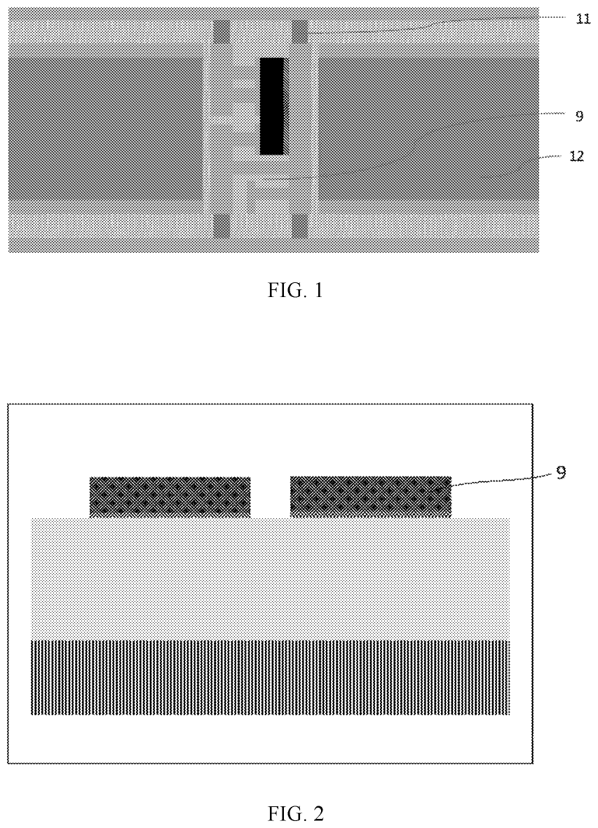

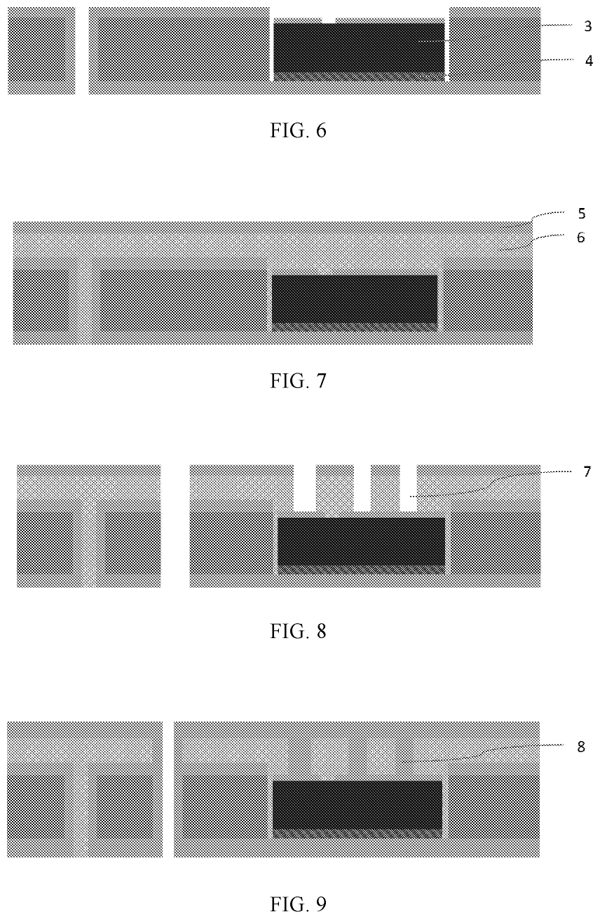

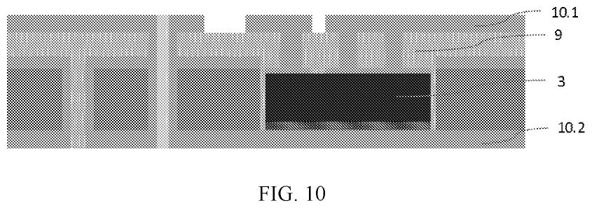

As shown in FIG. 1 to FIG. 10, an embodiment of this application provides a method for applying a component-embedded packaging unit to a PCB. The method includes the following steps:
1. Drill, electroplate, and pattern a first PCB substrate 1 based on design requirements, as shown in FIG. 4.
2. Form a first recess 2 in a region for placing a component, and expose a first copper layer at the bottom of the first PCB substrate 1, as shown in FIG. 5.
3. Attach the component 3 to the first copper layer through a soldering layer 4 formed by silver-sintering or eutectic soldering or other means, as shown in FIG. 6.
4. Laminate prepreg 6 and copper foil 5 stacked on the first PCB substrate 1 to which the component is attached, as shown in FIG. 7.
5. Form, on the top of the component, a second recess 7 above a region from which external conduction is required, and drill vias in the laminated first PCB substrate 1 based on design requirements, as shown in FIG. 8.
6. Perform copper electroplating on the second recess 7 at the top of the component to form a metallized filler layer 8, and electroplate and metallize the drilled vias.
7. Electroplate and thicken the first copper layer on the top and the bottom of the laminated first PCB substrate 1, so that the first copper layer is thickened by at least more than 2 oz, as shown in FIG. 9.
8. Create a surface pattern based on the circuit design to form a top lead 10.1 and a bottom lead 10.2 of the component.
9. Further metallize the surface of the first PCB substrate 1 as required.
10. Fabricate a component-embedded packaging unit 9 as designed, as shown in FIG. 10.
11. Fabricate a second PCB substrate 12, drill vias in the second PCB substrate based on design requirements to generate cavities, vertically embed the component-embedded packaging unit 9 in the cavities, stack prepreg and copper foil in the vertical direction and laminate them together, create metallized vias 11 in the vertical direction in the lead region, and vertically embed the component-embedded packaging unit 9 in the PCB to implement electrical conduction in the PCB, as shown in FIG. 1.

The first PCB substrate 1 may be a single core board or a whole formed by laminating a plurality of core boards. The thickness of the first copper layer at the bottom of the first PCB substrate is greater than or equal to 1 oz, and the board thickness is greater than the thickness of the component 3. The drilling, electroplating, and patterning may be selectively performed based on the circuit design of the component 3.

The first recess 2 is formed in the region at which the component 3 is placed. The dimensions of the first recess are larger than dimensions of the component 3, with a single-side clearance ranging from 100 μm to 300 μm.

The component 3 may be attached by means including but not limited to the silver-sintering and eutectic soldering described in the example, and may be attached by other bonding means.

The metallization of the second recess 7 and the drilled vias on the top of the component 3 may be performed by means including but not limited to the electroplating described in the example, and may be performed by other metallization means.

The thickness of the copper surface on the top and the bottom of the PCB board is increased by electroplating, and the thickness of the copper surface depends on the circuit design and the current of the component 3.

The top lead 10.1 of the component extends to and is exposed at the sidewall through the metal-filled second recess 7 and an etched pattern. The bottom lead 10.2 of the component extends to and is exposed at the sidewall through the soldering layer 4 and an etched pattern.

The surface of the laminated first PCB substrate 1 may be further metallized optionally depending on the circuit design of the component 3.

One or more components or different types of components 3 may be embedded in the component-embedded packaging unit 9 as designed.

The second PCB substrate 12 may be one core board or a whole formed by laminating a plurality of core boards. Dimensions of the cavity are larger than dimensions of the component-embedded packaging unit 9, with a single-side clearance ranging from 100 μm to 200 μm. The thickness of the second PCB substrate 12 matches the thickness of the component 3, with a deviation within +/−100 μm. All structural designs in which the component-embedded packaging unit 9 is vertically embedded and metallized vias are created in the vertical direction through leads to implement electrical conduction in the PCB fall within the technical solution hereof.

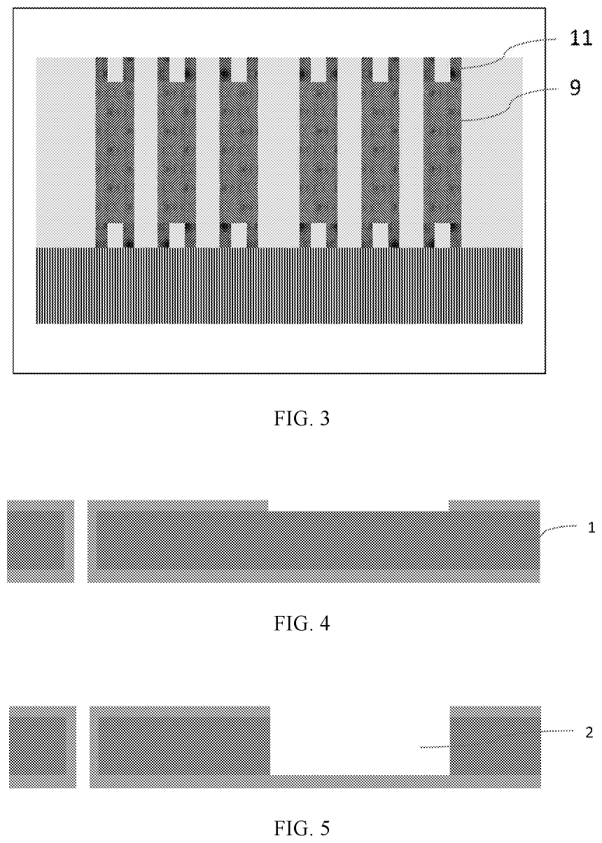

As shown in FIG. 2, a conventional component package is attached to the surface of the substrate to form a conventional planar power supply structure. In the technical solution hereof, the component-embedded packaging unit 9 fabricated herein is vertically embedded in the PCB, and metallized vias 11 are created above and below the lead to form a vertically embedded structure in the PCB, as shown in FIG. 3, so that the planar footprint of the unit is reduced. For the same current-carrying capacity, the current-carrying density per unit area is increased to 3 times that of the conventional structure. In addition, the heat dissipation distribution is improved, and the losses are reduced, which is of far-reaching significance.

The foregoing descriptions are merely preferred embodiments of this application. It is noted that various improvements and variations, which may be made by a person of ordinary skill in the art without departing from the technical principles of this application, shall still fall within the protection scope of this application.

What is claimed is:

1. A method for applying a component-embedded packaging unit to a PCB, comprising:
processing a second PCB substrate based on design requirements to form a cavity, wherein a second copper layer is provided on a surface of the cavity-formed second PCB substrate;
embedding the component-embedded packaging unit into the cavity vertically; and
laying prepreg and copper foil on a surface of the second copper layer sequentially, performing lamination, forming an externally connected laser via at a lead of a component, and electroplating the laser via with copper to enable electrical connection in the PCB.

2. The method for applying a component-embedded packaging unit to a PCB according to claim 1, wherein a manufacturing process of the component-embedded packaging unit comprises:
drilling a via in the first PCB substrate based on design requirements and performing copper electroplating so that a first copper layer is provided on a surface of the first PCB substrate, and performing pattern design on the first copper layer to generate a placement region;
forming a first recess in a preset placement region of the first PCB substrate, and extending a bottom of the first recess to the first copper layer at a bottom of the first PCB substrate;
attaching the component to the first copper layer at the bottom of the first recess;
laying prepreg and copper foil on a component-attached side of the first PCB substrate sequentially, and performing lamination;
forming a second recess in the prepreg and the copper foil to enable external conduction of the component;
performing copper electroplating on the second recess at a top of the component to generate a metallized filler layer;
performing copper electroplating on a top surface and a bottom surface of the laminated first PCB substrate to thicken the surfaces and form a thickening copper layer on each of the surfaces; and
performing pattern design on the thickening copper layer to form a top lead and a bottom lead of the component and obtain a finished component-embedded packaging unit.

3. The method for applying a component-embedded packaging unit to a PCB according to claim 2, wherein during the electroplating on the top surface and the bottom surface of the laminated first PCB substrate to thicken the surfaces, the surfaces are thickened by at least more than 2 oz.

4. The method for applying a component-embedded packaging unit to a PCB according to claim 2, wherein the component is attached to the first copper layer through a soldering layer formed by silver-sintering or eutectic soldering.

5. The method for applying a component-embedded packaging unit to a PCB according to claim 4, wherein the bottom lead of the component extends to and is exposed at a sidewall through the soldering layer and an etched pattern, and the top lead of the component extends to and is exposed at the sidewall through a metal-filled second recess and an etched pattern.

6. The method for applying a component-embedded packaging unit to a PCB according to claim 1, wherein dimensions of the cavity of the second PCB substrate are larger than dimensions of the component-embedded packaging unit, with a single-side clearance ranging from 100 μm to 300 μm; and a thickness of the second PCB substrate matches a thickness of the component, with a deviation within +/−100 μm.

7. The method for applying a component-embedded packaging unit to a PCB according to claim 2, wherein the first PCB substrate/second PCB substrate is a single-layer core board or a whole formed by laminating a plurality of core boards.

8. The method for applying a component-embedded packaging unit to a PCB according to claim 2, wherein a thickness of the first copper layer at a bottom of the first PCB substrate is not less than 1 oz, and a board thickness is greater than a thickness of the component.

9. The method for applying a component-embedded packaging unit to a PCB according to claim 1, wherein dimensions of the first recess are larger than dimensions of the component, with a single-side clearance ranging from 100 μm to 200 μm.

10. The method for applying a component-embedded packaging unit to a PCB according to claim 1, wherein one or more components are embedded in the component-embedded packaging unit.
